(19) United States
(12) Patent Application Publication
(10) Pub. No.: US 2004/0001015 A1
(43) Pub. Date: Jan. 1, 2004

(54) Processing analog signals with respect to timing of related rotary parts

(76) Inventor: John E. Games, Granby, CT (US)

Correspondence Address: Gregory R. Stephenson, One Hamilton Road, MS 1-1-BC18, Windsor Locks, CT, 06096, US

(21) Appl. No.: 10/608,699

(22) Filed: Jun. 27, 2003

Related U.S. Application Data
(63) Continuation of application No. 10/039,193, filed on Dec. 31, 2001, now abandoned.
(60) Provisional application No. 60/259,353, filed on Dec. 30, 2000.

(51) Int. Cl. H03M 1/48

(52) U.S. Cl. 341/112

(57) ABSTRACT

Vibration signals (20, 21) are filtered and integrated (26) and converted to digital signals (41), resolved into orthogonal components (82, 180, 185; 96, 140, 145) of angles (81, 95) related to rotary components (43, 90). The pulse frequency of a stream of input pulses from the rotary components is multiplied (45, 92) by 2ⁿ, by inserting (32) a pulse for each ½ⁿ fraction (26, 28, 31) of the period (11, 15) following the preceding pulse. The averaging (192, 205; 152, 165) of the sums (189; 149) of the squares (182, 187; 147, 142) of the orthogonal components is started leaving enough time for maximum deceleration at current speeds. Conflict in use of A/D (41) is resolved by registering the output (123; 124) in both channels. Square wave signals (23) are used for built-in test interleaved with signal processing. Non-integer pulses per revolution are accommodated with a counter (95) that counts modulo-one-bit-higher than a small integer multiple of a number close to the non-integer number.

### PRIORITY DATA

This application is a continuation of U.S. patent application Ser. No. 10/039,193, filed Dec. 31, 2001, entitled “Vibration Tracking Filter”, which claims the benefit of U.S. provisional patent application serial No. 60/259,353, filed Dec. 30, 2000, entitled “Vibration Tracking Filter”.

### GOVERNMENT RIGHTS

This invention was made with U.S. Government support under Contract No. F33657-97-C-0016. The government may have certain rights in the invention.

### TECHNICAL FIELD

This invention relates to processing analog signals such as vibration-indicating signals by filtering, integrating, converting to digital signals in response to said rotary signals and resolving into orthogonal components, of which the sum of the squares are determined and averaged. Pulse frequency multiplication, shared A to D, start of averaging, determining sines and cosines of non-integer pulses per revolution, and built-in test using square waves of which the higher harmonics are filtered out are involved in the processing.

### BACKGROUND ART

When an analog signal is to be sampled for A/D conversion in response to signals received from a rotating device, so as to permit resolving the analog signal into its orthogonal components with respect to the instantaneous angle of the rotating device, aliasing may occur near harmonics of the sample frequency. In order to avoid that, the timing sampling signals may have the frequency thereof multiplied so as to avoid the aliasing. However, frequency multiplication circuits that can multiply signals of a randomly varying frequency and different phases, for example, phase lock loops, are complex and require extensive circuitry to implement.

When processing signals through a multiplexer, signal conditioners and an A/D converter, it is most economical if a single channel can be used to process signals at a plurality of different timing sequences. If the timing sequences are at mutually unrelated frequencies and have no set phase relationship, many A/D conversions may be made without conflict between them. However, when an A/D conversion has been started by one stream of control signals, and another A/D conversion is requested by another stream of control signals, a conflict exists; if the conflict is not resolved, a set of data can be lost.

When signal conditioning circuitry, including bandpass filtering and integrating, feeding an analog to digital converter, are shared by a plurality of input signals, which are selected by a multiplexer, there is a need for a settling time when the multiplexer switches from one input to another input before the output of the signal conditioning circuit fairly represents the selected input signal due to the need to allow the integrator and bandpass filters to settle on the new value. If the sampling rate of the A/D converter is not constant, and particularly, if it may become slower as the result of deceleration of a moving part or other factor, the amount of time for settling, within a fixed processing cycle, may vary. Therefore, the amount of time which can be allocated to averaging of signals within that fixed cycle may vary in dependence upon whether the timing sampling signals are slowing down or not.

To resolve components of a signal into orthogonal components at angles of a related rotating part, it is common to utilize lookup tables of the desired functions in response to the angles of the rotating part. However, if the rotating part has a non-integer number of pulses per revolution, table look-up does not seem to be appropriate.

When signals which are processed from sensors of real time phenomena are used either to control or to monitor the safety of equipment in use, and particularly equipment in use in flight, such as aircraft jet engines, correct operation of the signal processing apparatus must be assured. For this purpose, it is known to utilize built-in test equipment (BIT) to periodically test critical signal processing channels to determine the viability thereof. When the processing involves the frequency and amplitude of AC signals, the utilization of sine waves as test signals may be involved. Sine waves may be generated by oscillators, of course, which requires a fair amount of circuitry per oscillator, most oscillators being operable only at one frequency, or possibly at several frequencies with auxiliary apparatus. When many frequencies are involved, many oscillators would be required. Sine waves may be synthesized stepwise and smoothed, but this requires significant digital processing, particularly for a large number of frequencies that may be used.

### DISCLOSURE OF INVENTION

Objects of the invention include: providing simple multiplication of pulse frequencies on a rapid real time basis; allowing signals sampled at two different rates to utilize the same filtering, integrating and A/D conversion channel, without loss of samples due to conflicts between the diverse sampling rates; determining the maximum time which is required for signal processing, thereby allocating as much time as possible to settling of signals, after the input to bandpass filter and integration circuitry has changed from one input signal to another; provision of a simple table lookup of trigonometric values of angles of a rotating part which provides a non-integer number of pulses per revolution; and provision of a simplified source of test signals for testing sinusoidal signal processing channels involving filters.

This invention is predicated in part on the realization that pulses may be inserted between the pulses of a stream, so as to multiply the pulse frequency thereof, utilizing the period between a given pulse and the next preceding pulse as a determination of the length of each fraction of a period when a pulse should be inserted. This invention is further predicated on the concept that conflicting demands for A/D conversion of filtered and integrated analog signals need not result in loss of samples if the conversion for one of the timing signals is used as the conversion for the conflicting timing signal. The invention is predicated in part on the discovery that a lookup table of trigonometric values, corresponding to a non-integer number of pulses per revolution from a sensor of a related rotating part, can be approximated by selecting a different number of pulses per revolution which is close to the actual non-integer number, and using a count of a small integer multiple of that different number of pulses to provide repetition of the trigonometric values desired. This invention is also predicated in part on the realization that the effect of upper harmonics of lower frequency components of a square wave, whose magnitude is adjusted upwardly by 4/π to produce a sinusoidal fundamental frequency at the amplitude and frequency of a sine wave of interest, is predictable.

According to the present invention, analog signals, such as from a vibration sensor, are processed first through a single channel of filtering, integration and conversion to digital signals, and then through a plurality of channels in which the signals are resolved into orthogonal components in accordance with the instantaneous angles of related rotary parts having sensors which emit pulses per revolution; the pulse frequency is multiplied by inserting bits between the bits from the sensors; maximum settling time for filters and integrators following switching from other signals, such as square wave test signals, or other sources, is achieved by starting the processing in each separate channel at a point in time which allows just sufficient time to accommodate a maximum deceleration in that channel from current speed; if one channel seeks to start the A/D while it is processing for the other channel, the digital output is used in both channels; non-integer number of pulses per revolution of a sensor is accommodated by counting modulo-one-bit-higher than a small integer multiple of another number close to the non-integer number of interest; built-in test passes square waves through all of the processing channels in an interleaved fashion with input signals, the predictable response of the processing channels to the square wave being indicative of either proper functioning or fault in the processing channels.

According to the present invention, the period between one pulse and the next preceding pulse is divided into N, and N minus 1 additional pulses are inserted between each pulse and the next succeeding pulse, thereby to provide pulse frequency multiplication. More than one rate of sampling of an analog input is made by an analog to digital converter; according to the invention, whenever there is a conflict resulting from one sampling signal attempting to start to an A/D conversion while an A/D conversion is in process, the resulting digital output will be utilized not only for the signal that started the conversion, but also for the signal which is in conflict therewith. In further accord with the invention, the portion of a fixed cycle required for processing signals, such as averaging a large number of signals, which are sampled in response to timing signals from a rotary part related thereto, the time required for such processing in the event that the rotary part decelerates at a maximum predetermined deceleration rate is determined, and the processing is started at a corresponding time advanced from the end of the fixed cycle. In still further accord with the invention, provision of trigonometric functions of an input signal in dependence upon the angle of a rotary device which provides a non-integer of numbers per revolution, is determined by selecting a different number, integer or non-integer, of pulses per revolution, counting modulo a number which is a small integer times the selected number of pulses per revolution, and providing a lookup table of the desired trigonometric functions responsive to the count. In accordance with the invention still further, built-in test equipment which tests the channels for processing an analog signal utilizes square waves at an appropriate frequency, the third and higher harmonics of which are suppressed by the anti-aliasing filters of the signal processing apparatus.

Other objects, features and advantages of the present invention will become more apparent in the light of the following detailed description of exemplary embodiments thereof, as illustrated in the accompanying drawing.

### BRIEF DESCRIPTION OF THE DRAWINGS

FIG. 1 is an illustrative schematic block diagram of a system incorporating the invention.

FIG. 2 is a block diagram of signal conditioning circuits.

FIG. 3 is a schematic block diagram of a 2ⁿ pulse frequency multiplier according to the invention.

FIG. 4 is a logic flow diagram of a tracking filter state machine.

FIG. 5 is a partial table of sine and cosine values of fan angular rotation.

FIG. 6 is a partial table of sine and cosine values of gas generator angular rotation.

FIG. 7 is a time chart illustrating the determination of averaging start times according to the invention.

FIGS. 8 and 9 illustrate a three-pole filter.

### MODE(S) FOR CARRYING OUT THE INVENTION

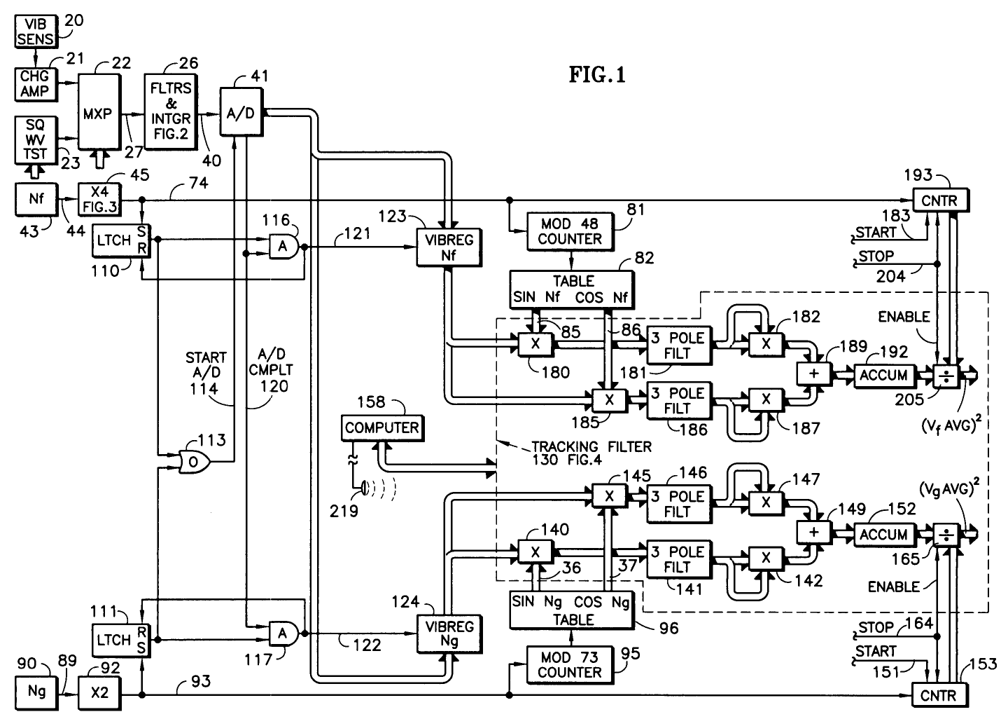

Referring to FIG. 1, an exemplary task which illustrates and utilizes the various aspects of the present invention is sensing vibration in a device such as a gas turbine engine which has two engine portions rotating at different speeds, such as a gas turbine engine fan and a gas turbine engine gas generator. The signals from the vibration sensor are analyzed to determine the magnitude of vibration related to each of the rotary speeds. However, it should be understood that aspects of the invention can be utilized when analyzing the output of a vibration sensor with respect to a single rotary frequency. Similarly, the invention may be utilized in a time division multiplex fashion to process the signals from two, three or more vibration sensors, or to analyze the output of the vibration sensors with respect to more than two rotary frequencies.

In FIG. 1, a vibration sensor 20 may comprise a piezoelectric accelerometer which provides signals to a charge amplifier 21. The output of the charge amplifier 21 may be selected by a multiplexer 22 so that the signal will be processed, or the multiplexer 22 may select signals from a square wave test signal source 23, as is described more fully hereinafter.

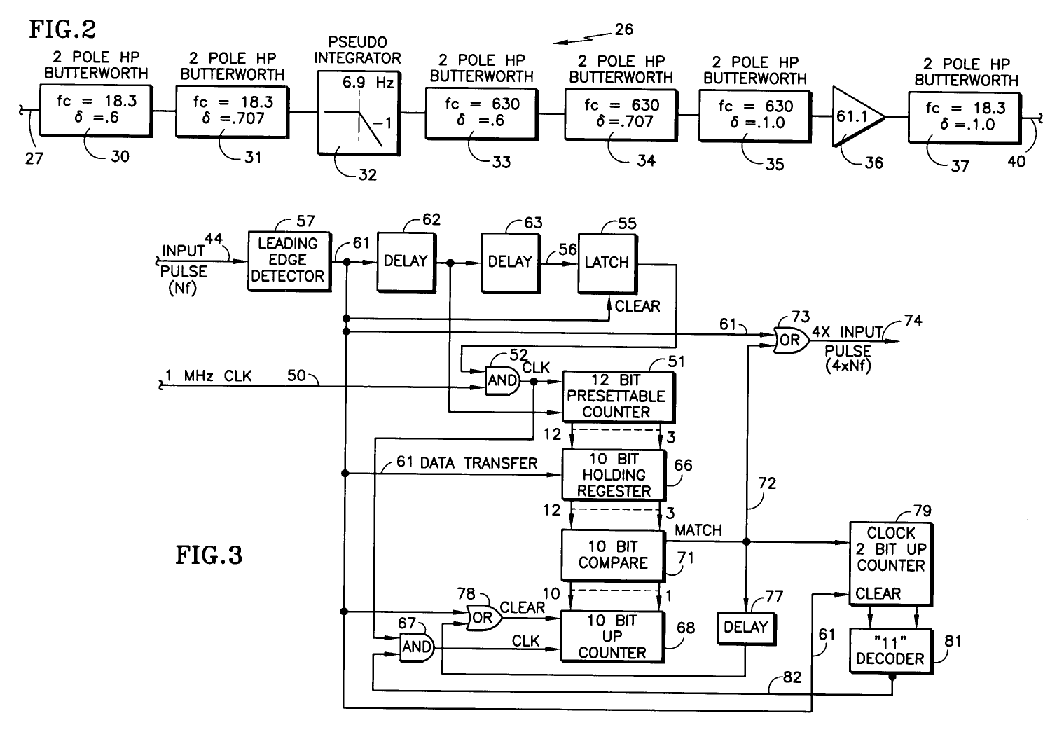

Whichever signal is selected by the multiplexer is provided over a line 27 to a circuit 26 of filters and an integrator which is illustrated in FIG. 2. In FIG. 2, a pair of high pass filters 30, 31 each have a cutoff frequency, fc, of 18.3 Hertz, the filter 30 having a damping factor, δ, of 0.6 and the filter 31 having a damping factor of 0.707. A low pass filter 32, which may be thought of as a pseudo integrator, converts the acceleration signal that has been passed through the high pass filters into a velocity signal. The output of the integrator 32 is passed through three low pass filters each having a cutoff frequency of 630 Hertz, with various damping factors as shown in FIG. 2. Then an amplifier 36 provides a gain of 61.1. Finally, a high pass filter 37 with a cutoff frequency of 18.3 Hertz and a damping factor of 1.0 completes the signal conditioning. The net effect of the low pass and high pass filters is band pass filtering of the input signal to avoid aliasing (the low pass filters) and to avoid low frequency noise (the high pass filters). The output of the signal conditioning circuitry 26 on a line 40 is applied to an analog to digital converter, A/D 41 (FIG. 1).

The A/D converter is caused to start in response to signals which are multiples of the speed sensor pulses, in this example, from the engine fan, Nf, and from the engine gas generator, Ng. In order to avoid aliasing errors, the output signal of an Nf speed sensor 43 is applied over a line 44 to a frequency multiplier circuit 45, which is illustrated in FIG. 3.

Referring to FIG. 3, a pulse frequency multiplier according to the present invention responds to the occurrence of each pulse, such as the pulses Nf indicative of fan speed in a gas turbine engine, by inserting a requisite number of pulses between one received input pulse and the next received input pulse. In the 4x example in FIG. 3, a pulse is inserted at one-quarter of the period after a received input pulse, a pulse is inserted at one-half of the period after a received input pulse, and a pulse is inserted at three-quarters of the period after a received input pulse. The measure of the period, and therefore the fraction of a period where a pulse should be inserted, is, however, based upon the actual period following the next preceding pulse, which is very nearly of the same period as the present pulse.

The period of the preceding pulse is manifested in the number of counts of a one megahertz clock signal which appears on a line 50, and is allowed to be counted in a 12 bit presettable counter 51 only when an AND circuit 52 is enabled by a latch 55. The latch 55 is set by a signal on a line 56 just after a leading edge detector 57 senses the presence of an input pulse on the line 44. When the leading edge detector senses an input pulse, it provides a data transfer signal on a line 61 that is fed to a delay circuit 62 which in turn has its output fed to a delay circuit 63. The delays in the delay circuits 62, 63 are on the order of a few microseconds and are present just to avoid glitches in the process of setting and clearing the latch 55. The data transfer signal on the line 61 resets the latch, thereby ending the passage of clock signals from the line 50 through the AND circuit 52 into the counter 51; that is how the counter is stopped to determine the extent of the period between the present input pulse and the next prior input pulse.

At the same time, the content of the 12 bit presettable counter 51, except for the two lowest order bits, is transferred into a 10 bit holding register 66 by the data transfer signal on the line 61. Just after the data is transferred from the 12 bit presettable counter 51 into the ten bit holding register 66, the output of the delay circuit 63 will again set the latch 55 so that counting of the present period can occur in the 12 bit presettable counter.

The data in the counter 66 is truncated by eliminating the first and second least significant bits. This is equivalent to a shift to the right (toward lower significance) and is equal to division by four. Therefore, the third through twelfth bits of the twelve bit resettable counter 51 represent the value of one-quarter of the period of the next preceding pulse-to-pulse interval.

When the latch 55 is set, clock pulses which pass through the AND circuit 52 are applied not only to the twelve bit presettable counter 51 but also through another AND circuit 67 to cause a ten bit up counter 68 to count clock signals derived from the line 50. The output of the 10 bit up counter 68 is applied to a ten bit compare 71, and when it matches the value set in the 10 bit holding register 66, a match signal on a line 72 indicates that one-quarter of a period has elapsed. This signal passes through an OR circuit 73 to become part of the stream of 4× input pulse signals on a line 74. The signal on line 72 is also provided to a delay circuit 77, the output of which will pass through an OR circuit 78 to clear the ten bit up counter 68 to make it ready to count the next quarter of a cycle. The OR circuit 78 also responds to the data transfer signal on the line 61, indicating that an input pulse has just been received.

The signal on the line 72 is also provided to the clock input of a two bit up counter 79, the output of which is applied to a decoder 81 which will decode binary four (11) to provide a signal on a line 82 that will inhibit the AND circuit 67, thus preventing clock signals from occurring during the fourth quarter of the period. The reason being that the fourth pulse will be that provided as the data transfer signal by the leading edge detector 57 when the next input pulse is received on the line 44. The match signal on line 72 will be provided at the end of the first, second and third quarters, and the actual input pulse, provided by the leading edge detector 57 onto the line 61, will provide the fourth pulse. Thus, there are four times as many pulses on the line 74 as are received on the line 44, effectively multiplying the input pulse frequency by four.

In the 4× example herein, n=2, and ½ⁿ is equal to one quarter; 2ⁿ=four.

The embodiment described in FIG. 3 multiplies the frequency of input pulses by four. This is because the data in the 12 bit presettable counter 51 is truncated by four, by dropping the two lowest order bits, meaning that the data is divided by four; this results in the match signal on line 72 being generated every quarter of a cycle. If the output of the 12 bit resettable counter was truncated by three bits, equal to a division by eight, then the match signal on line 72 would be present every eighth of a cycle. Similarly, any power of two may be selected, and adjustment of the truncation of data at the output of the twelve bit resettable counter 51 will accomplish the desired frequency multiplication of the pulse stream. Thus, multiplying the frequency of input pulses by 2n (which is 4 in FIG. 3) is accomplished by truncating to eliminate the n lowest ordered bits (2 in FIG. 3).

The frequency of a signal on a line 89 from the Ng speed sensor 90 is doubled in a frequency multiplication circuit 92, which may be the circuit of FIG. 3, truncated by only one bit.

As an example, in this embodiment, there is only one vibration sensor, but a useful case would have two vibration sensors. For instance, one at the front of the engine and one at the rear of the engine, both mounted on stationary engine portions. Only one of the vibration signals would be processed through the signal conditioning filters and the A/D converter at one time. The vibration signal is processed to see what vibration components there are at the speed of the gas generator and to see what vibration components there are at the speed of the fan. These speeds are not synchronous or bearing any phase relationship to each other, and the amount by which the gas generator speed may exceed the fan speed can vary at all times. As an example herein, we may consider a situation where the gas generator speed is on the order of three times greater than the fan speed, with no known phase relationship, and with the relationship between the two changing continuously. According to the invention, instead of having a full processing channel for Nf and a full processing channel for Ng, a single channel of processing can be initiated by either Nf or Ng because there are many times when there will be no interference between one pulse and the other. When there is a conflict between one A/D conversion being in process when another A/D conversion would be requested (but for the conflict), the problem is solved simply by utilizing the A/D output as the data value for the train of signals at one frequency (e.g, Ng) as well as for the train of signals at the other frequency (e.g., Nf). This poses no problem since the A/D conversion data is the same for either pulse rate except for a slight difference, which might occur due to the slight difference in timing when the A/D conversion is requested. It should be noted that the sampling of the vibration sensor may occur in response to a pulse from either of the speed sensors. By definition, if there is a conflict (that both of these sensors are providing an A to D request at times which are near one another), the data at one of those times is going to be very closely the same as the data at another of one of those times. The conflict is resolved simply by allowing the signal that will load the A/D into the Ng register to also load the A/D into the Nf register (or vice versa). In addition to loading the A/D into both registers 123, 124, the system will increment the sequence counters 81, 95 for both Ng and Nf. The A/D complete signal comes a little sooner with respect to the data that might have been generated by the second signal.

In FIG. 1, the signals Nf×4 on line 74 and Ng×2 on line 93 are each applied to a latch 110, 111. The output of both latches is fed to an OR circuit 113 which provides a start A/D signal on a line 114. The A/D converter will then begin the process of converting whatever analog value was present at its input, into a digital value in a known fashion. Either latch 110, 111, will remain set until a signal from a corresponding AND circuit 116, 117 responds to a concurrence of the set condition of the latch and an A/D complete signal on a line 120 to provide a related load A/D to Nf register signal on a line 121 or a load A/D to Ng register signal on a line 122. Each of these signals will reset the corresponding latch 110, 111.

If one of the latches, for example, 110, has been set and the A/D converter has been started, the A/D converter will be in the process of converting a signal related to Nf. If before it finishes, a signal is received on the line 89 so that the latch 111 becomes set, another start A/D signal will appear on the line 114. However, this will elicit no response in the A/D converter. The latch 110, however, will remain set. Thus, when the A/D completes conversion of the signal relating to Nf, the A/D complete signal on the line 120 will pass through both AND circuits 116, 117 and cause the digital value of the vibration sensor signal converted in response to the Nf signal to be loaded into both the Nf register 123 and the Ng register 124. In short, when the timing of the fan speed and gas generator speed conflict by being within an A/D conversion time of each other, the first signal causes an A/D conversion, the digital signal will appear in the stream of digital signals relating to the second signal, but at a timing determined by the first signal, which will be advanced in time by a small amount from one that would have been converted in response to the second signal. It has been shown that such slight advance in a conflicting signal has no effect on system performance.

This aspect of the invention will work with signals which are of the same or different, fixed or variable frequencies, and of fixed phase relationship or having no phase relation, so that conflicts can exist; however, it is most valuable when used with a pair of signals each of which can vary in frequency and phase independently of the other.

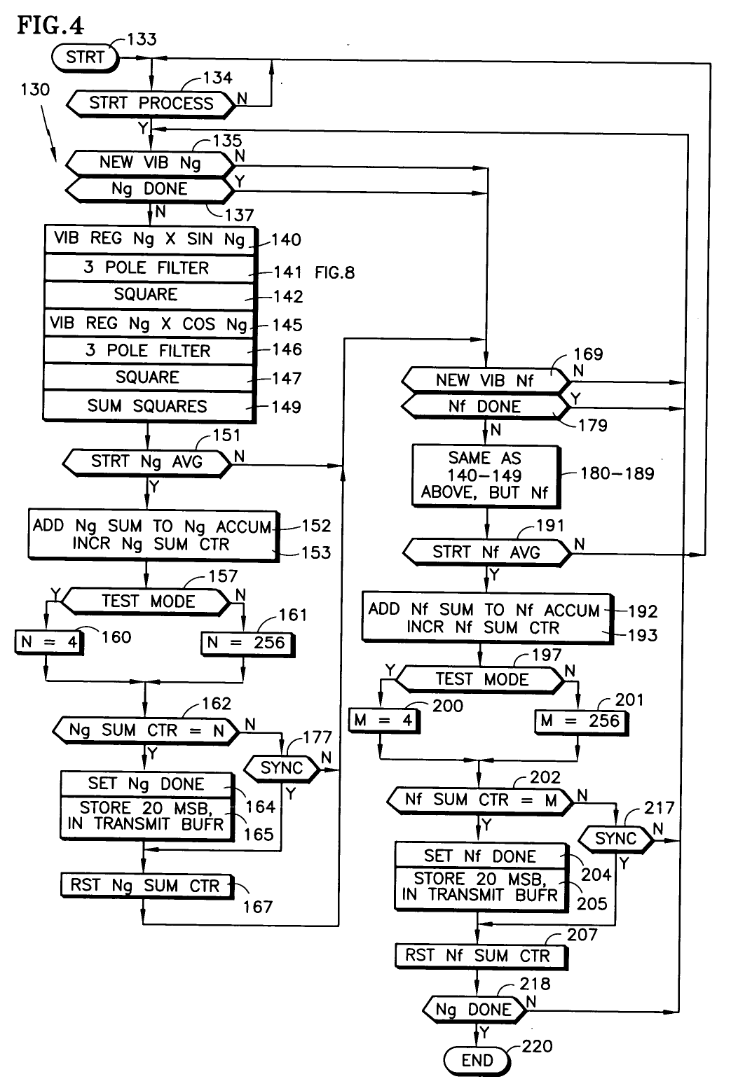

A tracking filter 130 is shown in analog fashion within the dash lines in FIG. 1, and is illustrated in a manner in which it may be performed digitally, in an application specific integrated circuit, by means of the state machine shown in logic flow format in FIG. 4. In FIG. 4, the routine may begin at a start entry point 133, and a first test 134 determines if a start process signal has been received, indicating that the processes should begin. Until the start process signal is received, the routine cycles on the test 134.

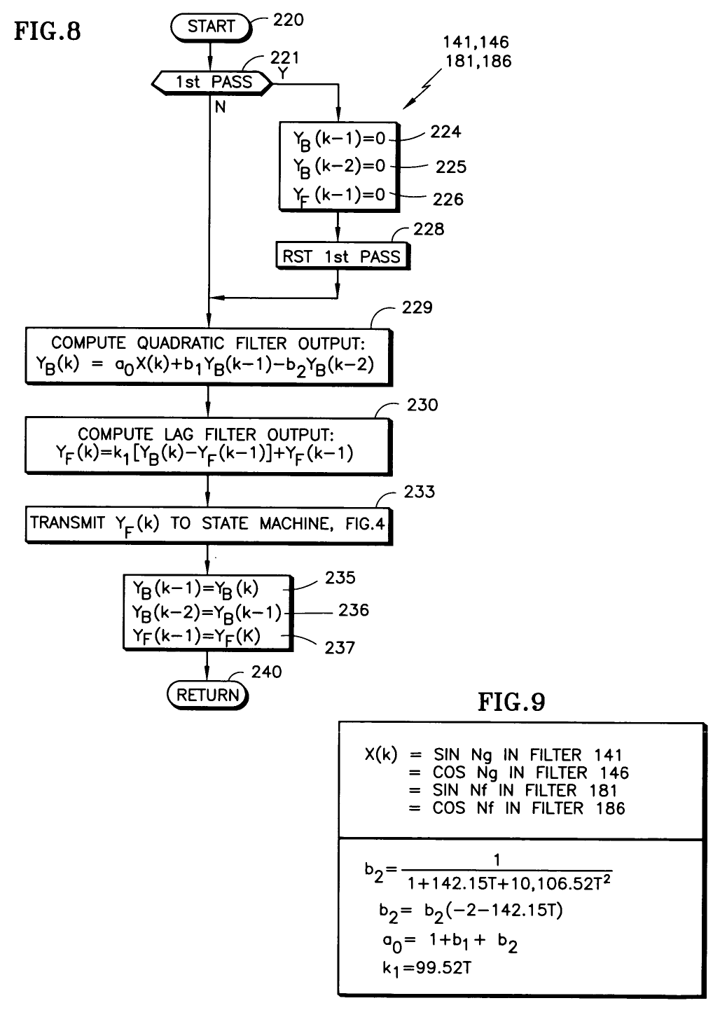

When the start process signal appears, an affirmative result of test 134 will reach a test 135 to determine if a new value of vibration signal has been entered into the Ng vibration register 124 (FIG. 1) or not. This is so when the latch 111 is set. If so, an affirmative result of test 135 will reach a test 137 to determine if either 256 iterations for regular signal processing, or 4 iterations for built-in test of the Ng channel, have been completed. If not, a negative result of test 137 reaches a subroutine 140 to multiply the content of the vibration register for Ng times the sine of Ng. Then a three pole filter subroutine 141 is performed on the product, in a manner described more fully hereinafter with respect to FIGS. 8 and 9. Then the filtered product is squared in a subroutine 142. Similar subroutines 145-147 provide the square of the filtered product of the vibration register Ng times the cosine of Ng. A subroutine 149 then provides the sum of the squares.

Reference to the lower central portion of FIG. 1 illustrates in analog fashion, with the same reference numerals, the functions which have just been described.

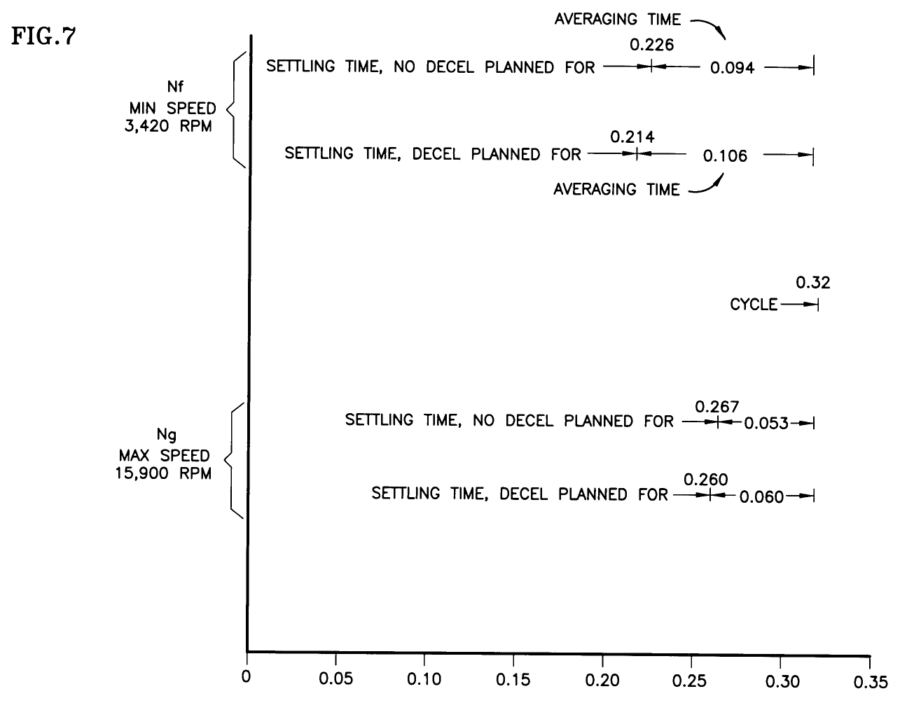

In FIG. 4, a test 151 determines if there is a signal, described hereinafter with respect to FIG. 7, indicating that it is now the proper time to begin averaging of the sums of squares derived as just described, over a large number of samplings of the vibration sensor, for data sampled at a rate related to the speed of the gas generator (Ng). If averaging is to begin, then a step 152 adds the recently derived sum of the squares into the content of an accumulator and a sum counter for Ng is incremented in a step 153.

A test 157 determines if the apparatus is currently in a test mode, or not. This determination is made by cycle control software in a computer 158 (FIG. 1) which also determines the square wave test pattern from the source 23 and the selection to be made by the multiplexer 22, as described hereinbefore. If the apparatus is in a test mode portion of a major cycle, a counting number, N, is set equal to four in a step 160. But if the test mode is not in effect, a negative result of test 157 reaches a step 161 to set N equal to 256. Then a test 162 determines if the sum counter has reached the count of N, or not. If it has, that means 256 real samples or four test samples have been accumulated in step 152. A step 164 sets an Ng done flag, and a step 165 divides the amount achieved in the accumulator step 152 by 256; this is achieved by storing only the 20 most significant bits of a 28 bit word in the transit buffer. Truncating the eight lowest ordered bits is equivalent to division by 256. Then a step 167 will reset the Ng sum counter, which had been incremented in step 153, and the routine will revert to a test 169 to see if the latch 110 (FIG. 1) is set, indicating a new vibration sample for Nf.

If a test 162 is negative, meaning that the averaging process is continuing, a test 177 determines if a communication synchronization signal has been received from the computer or not. If it has, this means that the subcycle of processing Ng has ended (which will not usually be the case) so that the sum counter must be reset and the routine ended. However, during the averaging process until the sum counter reaches N, if there is no synch signal, then processing of vibration values at the Nf rate can occur.

If either test 135 is negative (meaning there is no new word to process relative to Ng), or if test 137 is affirmative (indicating that processing for Ng is done), or if test 151 is negative (indicating that the time to begin averaging of the Ng results has not yet arrived), or test 177 is negative (indicating that a sync termination has not occurred, or if the sum counter is reset (in step 167), the test 169 is reached at the beginning of the processing for vibration values at the Nf rate.

If there is no new vibration value in the Nf vibration register 123, a negative result of test 169 reverts the program back to processing for Ng. But if there is a new value, then a test 179 determines if the Nf done flag has been set yet or not. If not, then a series of subroutines 180-189, identical to the subroutines 140-149 but relating to Nf instead of Ng, are performed. Then a test 191 determines if a signal has been received indicating that it is time to start averaging for values related to Nf. If it is not yet time, then processing reverts to test 135 for processing vibration values relating to Ng. If averaging can begin, then a series of steps and tests 192-217 perform the same functions as steps and tests 152-177, described hereinbefore, except with respect to Nf instead of with respect to Ng. Then a test 218 determines if Ng processing is done; if not, the routine reverts to test 135. But if so, the routine will terminate through an end point 220. The averaging of Nf values is thus interleaved with the averaging of Ng values, and real values are interleaved with test values.

Each time the process ends through the point 220, it lays dormant until the next time that a start process signal causes an affirmative result of test 134, which is the beginning of a macro cycle in which these tests are performed. The test mode which is determined in tests 157 and 197 can simply be the second subcycle of a major cycle, the first subcycle being allocated to processing for Ng and Nf, respectively. If more speed sensors are used, more subcycles will be needed.

To provide the magnitude of vibration at the various angles of the gas generator as it rotates, or at the various angles of the fan as it rotates, the output of the A/D converter is resolved into orthogonal components relative to the sine and cosine of the rotational angle indicated by the respective speed sensors Nf, Ng. These are then filtered to eliminate sum frequencies above 10 Hertz, leaving only difference frequencies. These are then squared and summed so as to provide to the accumulator 152, 192 the sum of the squares of the resolved components, which equals the square of one-half of the instantaneous vector magnitude of the vibration signal.

Because accelerometers are subject to wide ranges of noise, which can render any particular reading non-representative of the actual vibration, averaging over a large number of samples may be desired. However, with the band pass filtering and integration of the signal conditioning circuits 26 of FIG. 2, maximum settling time should be allowed after switching inputs to the A/D converter 41 from test signals to vibration signals, or from one test signal to another. The amount of time which is available to provide averaging and the amount of time which is available for settling of the signals in the time shared signal conditioning of FIG. 2 must therefore be managed.

An exemplary situation is briefly illustrated in FIG. 7. When the multiplexer switches from a square wave test input back to the vibration sensor input, or vice versa, the signal conditioning filters and integrator 26 of FIG. 2 will take some settling time to actually settle at a present value of the vibration sensor or test signal. It is only after this adjustment to the vibration sensor or test signal that the A/D converter could provide actual digital representations of the vibration sensor or test magnitude. Since the definitive settling time can normally be established only by making it extremely long, instead, one aspect of the invention is allowing whatever settling time there can be while still permitting sampling 256 values of the vibration sensor within the allotted time of a cycle, and averaging as described with respect to FIGS. 1 and 4. If the rotational speed signals were constant, then a fixed amount of time could be reserved for averaging. Since, however, these speeds are not constant, care must be taken to allow sufficient time, even when there is a deceleration of either of the rotating members which the speed sensors Nf, Ng respond to.

The basic processing time for the minimum speed of the fan and for the maximum speed of the gas generator are given, only as examples, for use in establishing values on FIG. 7. A deceleration (decel) of 40% per second will be 13% in 0.32 seconds, the exemplary cycle time herein. Worst case allowance is therefore taken to be an increase of 13% in required time to average 256 samples, over the time that would be required at the current speed.

Nf:

min speed=3,420 RPM; 57 RPS

x 12 ppr=684 Hz

x 4 (FIG. 3)=2736 Hz

period per pulse=0.0003654 sec.

required sampling time for 256 pulses=0.0935424 sec.

remaining time, for settling=0.226 sec.

decel sampling time=x 1.13=0.1057029 sec.

remaining time, for settling=0.214 sec.

avg. finishes, if 40% decel, at 0.32 sec.

avg. finishes, if no decel, at 0.308 sec.

Ng:

max speed=15,900 RPM=265 RPS

x 9.138 ppr=2421.6 Hz

x 2=4843.2 Hz

period per pulse=0.0002064 sec.

required sampling time for 256 pulses=0.052884 sec.

remaining time, for settling=0.267

decel sampling time=x 1.13=0.0597073

remaining time, for settling=0.260 sec.

The resultant values stored in either the transmit buffer 165 (FIG. 1) or the transmit buffer 205 may be utilized for a variety of purposes. One purpose may be to have the computer 158 provide a signal to an annunciator 219 (FIG. 1) to indicate to personnel operating the related rotary apparatus that excessive vibration has occurred, when that is the case. Similarly, the data may simply be recorded for consideration by maintenance personnel at a later date, such as after a plane has landed.

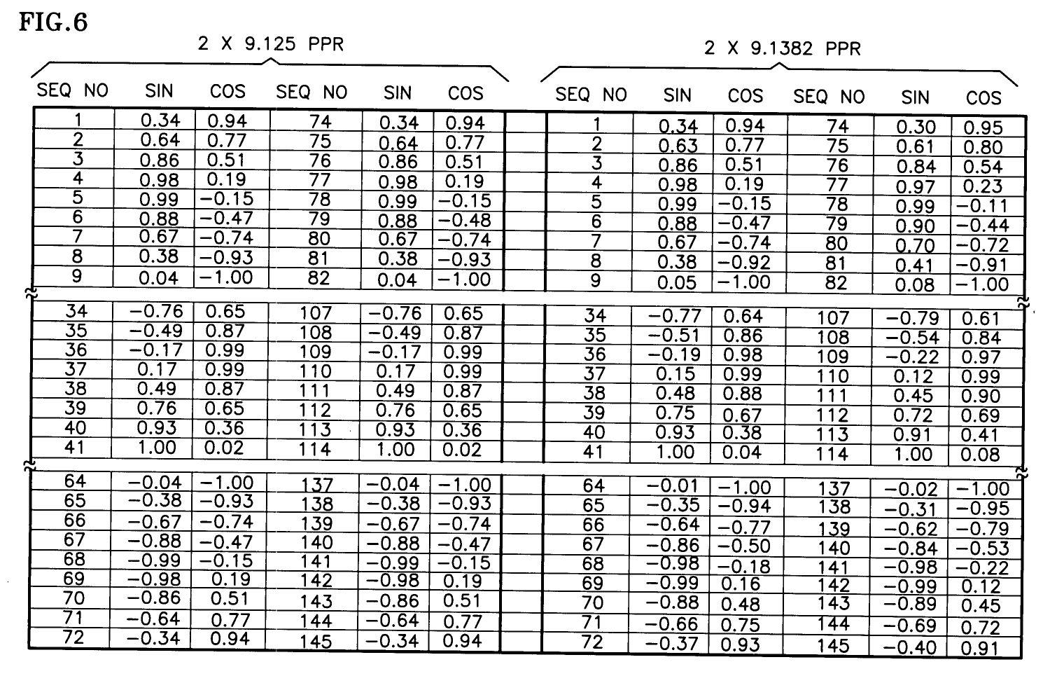

In FIG. 1, only a single vibration sensor 20 is shown. However, a second vibration sensor and corresponding charge amplifier, or even more of them, may be provided to the multiplexer 22, and the apparatus of FIGS. 1 and 6 will process all such vibration sensor outputs, one at a time. In the present embodiment, the apparatus may alternate between processing signals from the vibration sensor 20 and square wave test signals from the source 23. If additional vibration sensors are present, they may be processed contiguous with processing the vibration sensor 20, followed by processing of the square wave test signals, or the square wave test signals could, if desired, be interleaved with processing of a plurality of vibration sensors. Aspects of the invention, may, of course, be used with only one speed generator such as either Nf or Ng: and, if another channel of processing hardware and software is provided, the invention may be used with additional speed sensors. None of this is significant to the present invention.

It is intended that the Nf and Ng pulses determine the relative instantaneous angle of the fan and gas generator, and that they be utilized in a simple way to provide the sine and cosine of the angle of the fan and gas generator positions without any regard to an angular reference to a stationary position, or phase.

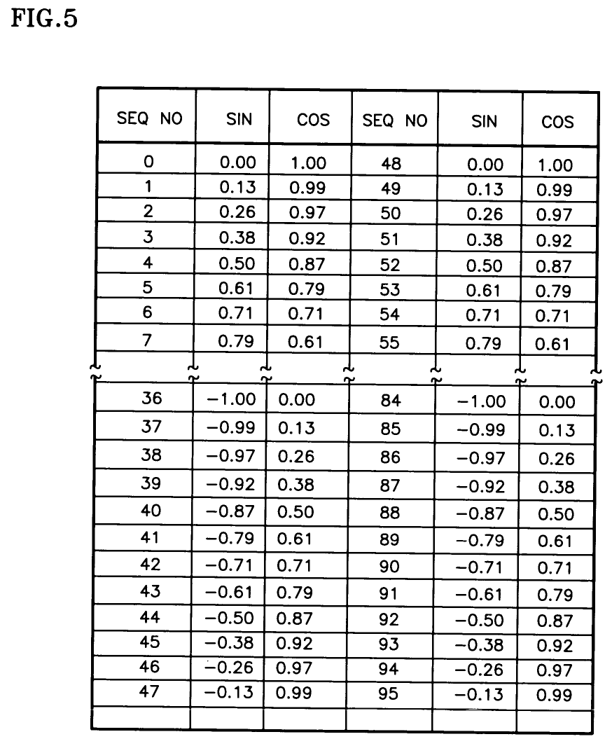

It can be shown that the sine and cosine values for a fan speed (Nf) counter issuing 12 pulses per second, which is multiplied by four to avoid aliased errors due to sampling, repeats identically every 48 pulses. Therefore, only 48 sets of sine and cosine values for the 12 pulse per revolution fan speed sensor is required. This is accomplished in FIG. 1 by a modulo 48 counter 81 feeding a lookup table 82 of sines and cosines. The content of the lookup table 82 is partially shown in FIG. 5, where the sequence number is the output of the modulo 48 counter 81.

One example of an application for digital compensation of a non-integer number of pulses occurring with respect to a related event, such as a revolution of a rotating device, is in a case where the speed counter on the gas generator of a gas turbine engine provides 9.138 pulses per revolution, such as Ng herein. In this example, to avoid aliased errors due to sampling, the pulses per revolution (referred to as frequency, at times herein) is doubled, and the result is desired to be used for table lookup of sine and cosine values thereof. However, if these values are used, the values continuously change, out to one thousand times, before there is any cyclic recurrence which would be utilized in an integer number of pulses per revolution. Therefore, a lookup table would require over nine million entries.

To handle the 9.138 pulses per revolution of the gas generator speed sensor, Ng, the invention first selects a more useful non-integer number, in this case 9.125, and then determines that the difference in sine and cosine values between two times 9.138 and two times 9.125 are acceptably close, within a very small percent of each other, which in most utilizations is negligible and can be ignored. A small integer multiple, in this case four, of the number of pulses per revolution, in this case 18.25 yields a table having entries which repeat, in this case 73 entries (0-72).

If there were 9 pulses per revolution, which are multiplied by 2, to provide 18 pulses per revolution, the sine and cosine values thereof would repeat identically every 18 pulses, and also every 72 pulses. According to the invention, assuming there are 9.125 pulses per revolution, and assuming those are doubled to 18.25 to avoid aliasing errors, then the sine and cosine values track almost perfectly and repeat after every 73^{rd} pulse. Thus, providing a table of sines and cosine values having 73 entries (that is, 73 values for successive input pulses) provides sine and cosine values which are adequately close in value to sine and cosine values that would be determined either by calculation or by an infinitely long storage device for the actual 9.138 pulses per revolution.

FIG. 6 is fragmentary, showing a comparison at the first few counts, some middle counts and at the last few counts, illustrating that the values utilizing 18.25 definitely repeat after 73 pulses numbered 0 through 72 (the 73^{rd} pulse being zero) and also illustrating the degree of likeness. For instance, for the 65^{th} pulse: the value of the sine of 4×18.25 pulses per revolution is −0.38 while the value for the sine of 4×18.276 pulses per revolution is −0.35. The maximum error is on the order of 0.14%.

Referring to FIG. 1, the Nf signal from the fan speed generator 43 is received on the line 44 and the frequency thereof is multiplied by four in the frequency multiplier 45, as described with respect to FIG. 3. These signals are applied on the line 74 to the modulo 48 counter 14 which simply counts the pulses and provides the count to the sine/cosine lookup table 82. The lookup table conforms to columns 1-3 of FIG. 4, referred to hereinbefore. The lookup table 82 provides the exact sine of Nf on a trunk of lines 85 and the exact cosine of Nf on a trunk of lines 86.

Similarly, the gas generator speed sensor pulses, Ng, are received on a line 89 from the gas generator speed generator 90, and multiplied by two in a multiplier 92, which may take the form of FIG. 3, but only truncating by one bit, so n=1, ½ⁿ is equal to one-half, and 2ⁿ=2. The doubled frequency signal is passed over a line 93 to a modulo 73 counter 95, the output of which is applied to a sine/cosine lookup table 96 which conforms to columns 1-3 of FIG. 5. The table 96 provides an approximate value of the sine of Ng on a trunk of lines 36 and an approximate value of the cosine of an Ng on a trunk of lines 37.

In this case, the number selected as a substitute for the number of pulses per revolution is itself a non-integer, but it is one for which a relatively low harmonic is an integer. In the general case, the invention may be practiced utilizing substitute numbers which are either integers or non-integers. The invention may of course be utilized to assist generating other trigonometric values of signals indicative of rotation.

In this case, a selected number, 9.125, is chosen to emulate input pulses having 9.138 pulses per revolution; the low harmonic of 9.125 is the eighth harmonic, having a value of 73. Some other harmonic could be chosen (but in this case it would be wasteful of apparatus and processing time); other choices may be made, either to get a more accurate approximation of the sine and cosine desired, or for other purposes.

An exemplary, conventional three pole filter suitable for use as three pole filters 141, 146, 181, 186 in FIGS. 1 and 4 is illustrated in FIG. 8. This filter will be performed by the state machine, for speed, by using constants which are derived in the computer 158 as a function of the period, T (as illustrated in FIG. 9), of the speed signals Nf, Ng on the lines 44, 89. The constants are illustrated in FIG. 9.

When a three pole filter subroutine is called in step 141, 146, 181, 186 of FIG. 4, the program will enter the three pole filter subroutine through a start point 220 and a first test 221 determines if this is the first pass or not since the start process 134 (FIG. 4). This will be determined by the cycle timing and synchronization provided by the computer 158 which will set a first pass flag in each filter. Initially, the first pass flag will be set in any of the filters, and a series of steps 224-226 will reset to zero those functions that are calculated and then used in subsequent passes. And then the first pass flag is reset in a step 228. A subroutine 229 will compute the quadratic filter output in accordance with the equation therein. Then a subroutine 230 will compute a lag filter output in accordance with the equation shown therein. The result of the filter is Y_{F} (k), which is the filtered value of X(k), is transmitted to the state machine, FIG. 4, in a step 233. Then all of the factors which are utilized in subroutines 229, 230 are updated in a series of steps 235-237. Then, the program reverts to point 142, 147, 182, or 187 in the routine of FIG. 4 through a return point 240 in FIG. 8.

The built-in test of the present invention is caused, by the computer 158, to be interleaved with processing vibration signals from the vibration sensor 20. A series of different tests are performed, at different frequencies, so as to test the entire apparatus at frequencies that are pertinent to the fan speed and the gas generator speed. The constants of FIG. 9 are calculated separately for groups of built-in tests or individual built-in tests. The computer 158 provides square wave signals at the desired sampling frequency. The amplitude of the square wave peak value (P) is determined for each of the individual test signals by the following relationship: P=4/πA, where A is the amplitude of the desired sine wave peak. The multiplexer 22 therefore has a plurality of square wave test inputs, even though only a single input from the square wave test source 23 is shown. Because of the bandpass filtering in the signal conditioning circuits 26, and the three pole filtering described with respect to FIG. 8, the response to the harmonics of the square waves provided by the square wave test source 23 can be predicted for a properly operating filter (FIGS. 2 and 8). Thus, one aspect of the present invention is testing of apparatus responding to signals having complex sinusoidal components by means of predicting the response of the fundamental and harmonic components of a related square wave. The results are indicative of the proper or improper functioning of the tracking filter.

Thus, although the invention has been shown and described with respect to exemplary embodiments thereof, it should be understood by those skilled in the art that the foregoing and various other changes, omissions and additions may be made therein and thereto, without departing from the spirit and scope of the invention.

I claim:

1. A method of processing a plurality of A/C analog input signals derived from different sources through a first processing channel including a shared bandpass filter, integrator and A/D converter, and through a plurality of second processing channels, each including resolution into orthogonal components as a function of the instantaneous angle of a corresponding one of a plurality of members rotating at different variable speeds and related to at least one of said analog input signals followed by low pass filtering, and providing, for each rotating member, an average of a plurality of sums of the squares of successive ones of said components corresponding to each of said sources, said method comprising:
(a) receiving a plurality of streams of input pulses from a plurality of angle-indicating sensors each indicative of rotation of a corresponding related member, said streams being of mutually unrelated frequencies, the frequency of either or both of which may be fixed or variable;
performing steps (b)-(d) for each of said streams—
(b) determining, for each pulse received, the particular period of time between each said pulse and the next preceding pulse thereto in said stream;
(c) determining, for each pulse received, each lapse of ½ⁿ of said period;
(d) providing a corresponding stream of control pulses, including one control pulse for each said input pulse and 2ⁿ−1 control pulses distributed between successive ones of said input pulses, and spaced by ½ⁿ of said period in response to said second step;
performing steps (e)-(g) for at least one of said streams of control pulses in which each pulse represents a non-integer function of a revolution—
(e) providing a plurality of look-up tables of trigonometric values of successive counts of angles corresponding to a selected number of pulses per revolution, which selected number may either be (i) an integer or (ii) a non-integer, a small integer multiple of which is an integer for which said trigonometric values repeat, and for which said trigonometric values are acceptably close to corresponding trigonometric values of angles corresponding to successive counts of said control pulses;
(f) counting said control pulses modulo m, where m is said small integer multiple of said selected number;
(g) applying the count derived in step (f) to said look-up table, thereby to derive the desired trigonometric functions approximately corresponding to the revolutions of said sensor;
(h) providing at least one analog input signal which is to be processed to evaluate at least one parameter thereof as it relates to each of said control signal streams;
(i) registering the occurrence of each control signal, separately for each of said streams, until completion of an A/D conversion started in step (j);
(j) starting an A/D conversion in response to registration of a control signal of any stream in step (i), unless an A/D conversion is in process;
(k) loading the result of each A/D conversion into at least one of a plurality of parameter registers, each said parameter register related independently to one of said plurality of control signal streams, said step of loading into at least one of said plurality of registers being responsive to completion of an A/D conversion concurrently with the registration of said step (i) of a control signal of a corresponding one of said streams, whereby if one of said control signals occurs while a particular A/D conversion is in process, the result of said particular A/D conversion will be loaded into one of said registers corresponding to said one timing signal as well as the one of said registers corresponding to the control signal which actually started said particular A/D conversion in said step (j);
(l) providing at least one square wave signal, each having a frequency within a range of frequencies of said A/C input signals and a magnitude related to a range of magnitudes of the related one of said A/C input signals;
(m) periodically selecting either an analog input signal from one of said sources or said square wave signal for application to said processing channels;
(n) defining a processing period within which said average is to be provided corresponding to the signal selected in step (m) after the output of said bandpass filter and integrator have settled on a value of the selected one of said signals following step (m);
(o) determining a given rate of deceleration which said members may undergo;
(p) determining, for each of said members, the time required to provide said average corresponding to said each member when said each member undergoes said given rate of deceleration from the corresponding current instantaneous speed of said member during said processing period;
(q) providing for each member, a start signal at a point in time advanced from the end of said processing period by said corresponding time required to provide said average, the time within said processing period preceding said start signal allowing settling of signals at the A/D converter input, each said start signal causing accumulation of said corresponding plurality of sums so that an average of each accumulation may be provided; and
(r) determining in response to said sums of the squares of successive ones of said components corresponding to said square wave test signal, the viability of processing through said processing channels.

2. Apparatus for multiplying the frequency of pulses, in a stream of input pulses, by 2ⁿ, comprising:
means for receiving pulses in said stream;
first means for determining, for each pulse received, the particular period of time between said each pulse and the next preceding pulse thereto in said stream;
second means for determining, for each pulse received, each lapse of ½ⁿ of said period; and
third means for providing a stream of output pulses, including one output pulse for each said input pulse and 2ⁿ−1 output pulses distributed between successive ones of said input pulses, and spaced by ½ⁿ of said period in response to said second means.

3. Apparatus according to claim 2 wherein said third means comprises:
means for issuing into a stream of output pulses, one output pulse upon each occurrence of determining said lapse, except the last occurrence related to each said input pulse, and one output pulse in response to each said input pulse, whereby 2ⁿ−1 output pulses are inserted in said stream of output pulses between successive input pulses.

4. Apparatus according to claim 3 comprising:
a source providing clock signals; and wherein said means for providing comprises:
a first counter for counting said clock signals during one period between input signals in said stream, to provide a count;
a register for maintaining the count of said clock signals divided by n during a second period between input signals in said stream next subsequent to said one period;
a second counter for counting clock signals;
a comparator for comparing the count in said second counter with the count in said register to provide a pulse for said output stream each time said counts are equal; and
means for preventing said second counter from counting more than 2ⁿ−1 times between each said input pulse.

5. A method of multiplying the frequency of pulses in a stream of input pulses by 2ⁿ, comprising:
receiving pulses in said stream;
first, determining, for each pulse received, the particular period of time between said each pulse and the next preceding pulse thereto in said stream;
second, determining, for each pulse received, each lapse of ½ⁿ of said period; and
third, providing a stream of output pulses, including one output pulse for each said input pulse and 2ⁿ−1 output pulses distributed between successive ones of said input pulses, and spaced by ½ⁿ of said period in response to said second step.

6. A method according to claim 5 wherein said means for providing comprises:
issuing into a stream of output pulses, one output pulse upon each occurrence of determining said lapse, except the last occurrence related to each said input pulse, and one output pulse in response to said each input pulse, whereby 2ⁿ−1 output pulses are inserted in said stream of output pulses between successive input pulses.

7. Apparatus for digitally compensating for a non-integer number of pulses-per-revolution from an angle-indicating sensor indicative of rotation of a related thing, said method comprising:
(a) means for providing a look-up table of trigonometric values of successive counts of angles corresponding to a selected number of pulses per revolution, which selected number may either be (i) an integer or (ii) a non-integer and has a small integer multiple which is an integer for which said trigonometric values repeat, and for which said trigonometric values are acceptably close to corresponding trigonometric values of angles corresponding to successive counts of said input pulses;
(b) means for counting said input pulses modulo m, where m is said small integer multiple of said selected number; and
(c) means for applying the count derived in element (b) to said look-up table, thereby to derive the desired trigonometric functions approximately corresponding to the revolutions of said sensor.

8. A method of digitally compensating for non-integer pulses-per-revolution input pulses from an angle-indicating sensor indicative of rotation of a related thing, said method comprising:
(a) providing a look-up table of trigonometric values of successive counts of angles corresponding to a selected number of pulses per revolution, which selected number may either be (i) an integer or (ii) a non-integer, and a small integer multiple of which is an integer for which said trigonometric values repeat, and for which said trigonometric values are acceptably close to corresponding trigonometric values of angles corresponding to successive counts of said input pulses;
(b) counting said input pulses modulo m, where m is said small integer multiple of said selected number; and
(c) applying the count derived in step (b) to said look-up table, thereby to derive the desired trigonometric functions approximately corresponding to the revolutions of said sensor.

9. A method of converting analog signals to digital signals in an A/D converter at a plurality of different sampling rates simultaneously, said method comprising:
(a) providing a plurality of sampling timing signal streams of mutually unrelated frequencies, the frequency of either or both of which may be fixed or variable;
(b) providing an analog input signal which is to be processed to evaluate at least one parameter thereof as it relates to both of said sampling timing signal streams;
(c) registering the occurrence of each timing signal, separately for each of said streams, until completion of an A/D conversion started in step (d);
(d) starting an A/D conversion in response to registration of a timing signal of any stream in step (c), unless an A/D conversion is in process; and
(e) loading the result of each A/D conversion into at least one of a plurality of registers, each said register related independently to one of said plurality of timing signal streams, said step of loading into each one of said plurality of registers being responsive to completion of an A/D conversion concurrently with the registration of said step (c) of a timing signal of a corresponding one of said streams, whereby if one of said sampling timing signals occurs while a particular A/D conversion is in process, the result of said particular A/D conversion will be loaded into the register corresponding to said one timing signal as well as the register corresponding to the timing signal which actually started said particular A/D conversion in said step (d).

10. Apparatus for converting analog signals to digital signals in an A/D converter at a plurality of different sampling rates simultaneously, comprising:
(a) means for providing a plurality of timing signal streams of different frequencies, the frequency of either or both of which may be fixed or variable;
(b) means for providing an analog signal which is to be processed to evaluate at least one parameter thereof as it relates to both of said sampling timing signal streams;
(c) means for registering the occurrence of each timing signal, separately for each of said streams, until completion of an A/D conversion started in element (d);
(d) means for starting an A/D conversion in response to registration of a timing signal of any stream in element (c) unless an A/D conversion is in process;
(e) means for loading the result of each A/D conversion into at least one of a plurality of registers, each said register related independently to one of said plurality of timing signal streams, said step of loading into at least one of said plurality of registers being responsive to completion of an A/D conversion concurrently with the registration by said element (c) of a timing signal of a corresponding one of said streams, whereby if one of said sampling timing signals occurs while a particular A/D conversion is in process, the result of said particular A/D conversion will be loaded into the register corresponding to said one timing signal as well as the register corresponding to the timing signal which actually initiated said particular A/D conversion in said element (d).

11. Apparatus for converting an analog signal to a digital signal at a plurality of different sampling rates simultaneously, comprising:
an A/D converter;
at least one sensor, each sensor providing an analog signal indicative of a condition of a corresponding part;
a plurality of rotation sensors, each related to a corresponding rotating portion of said part, each providing a stream of sampling timing signals, each signal of each stream representing a known fraction, which may be an integral fraction or a non-integral fraction, of a revolution of the corresponding rotating part;
at least one latch, each responsive to said sampling timing signals from a corresponding one of said rotation sensors to assume a first state and to simultaneously provide a start signal to said A/D converter;
a plurality of registers, one for each of said rotation sensors;
a plurality of means, one for each of said rotation sensors, each responsive to completion of an A/D conversion by said A/D converter, concurrently with the related latch being set in said first state, to set the corresponding latch into a state other than said first state and to cause the result of said A/D conversion to be stored in the related one of said registers, whereby if one of said sampling timing signals occurs while a particular A/D conversion is in process, the result of said particular A/D conversion will be loaded into the register corresponding to said one timing signal as well as the register corresponding to the timing signal which actually initiated said particular A/D conversion.

12. A method of processing a plurality of input signals derived from different sources through a processing channel including a shared bandpass filter, integrator, A/D converter, and resolution into orthogonal components as a function of the instantaneous angle of a member, rotating at variable speed and related to at least one of said input signals, and providing an average of a plurality of sums of the squares of successive ones of said components corresponding to one of said sources, said method comprising:
(a) switching said processing channels from a first one of said sources to a second one of said sources;
(b) defining a processing period within which said average is to be provided corresponding to said second source after the output of said bandpass filter and integrator have settled on a value of one of said input signals from said second source following step (a);
determining a given rate of deceleration which said member may undergo;
determining the time required to provide said average when said member undergoes said rate of deceleration from the current instantaneous speed during said processing period; and
providing a start signal at a point in time advanced from the end of said processing period by said time required to provide said average, the time preceding said start signal allowing setting of said value, said start signal causing accumulation of said plurality of sums so that an average thereof may be provided.

13. Apparatus for processing a plurality of input signals derived from different sources through a processing channel including a shared bandpass filter, integrator, A/D converter, and resolution into orthogonal components as a function of the instantaneous angle of a member, rotating at variable speed and related to at least one of said input signals, and providing an average of a plurality of sums of the squares of successive ones of said components corresponding to one of said sources, comprising:
(a) means for switching said processing channels from a first one of said sources to a second one of said sources;
(b) means for defining a processing period within which said average is to be provided corresponding to said second source after the output of said bandpass filter and integrator have settled on a value of one of said input signals from said second source following step (a);
means for determining a given rate of deceleration which said member may undergo;
means for determining the time required to provide said average when said member undergoes said rate of deceleration from the current instantaneous speed during said processing period; and
means for providing a start signal at a point in time advanced from the end of said processing period by said time required to provide said average, the time preceding said start signal allowing setting of said value, said start signal causing accumulation of said plurality of sums so that an average thereof may be provided.

14. A method of testing the viability of processing of an AC input signal, having a magnitude, through a processing channel including a shared bandpass filter and integrator, A/D converter, and resolution into orthogonal components as a function of the instantaneous angle of a member, rotating at variable speed and related to said input signal, and providing sums of the squares of successive ones of said components corresponding to said input signal, said method comprising:
providing a square wave signal having a frequency corresponding to frequencies of interest of said AC input signal and a magnitude of 4/π of a corresponding magnitude of interest of said AC input signal;
periodically selecting said square wave signal instead of said input signal for application to said processing channel; and
determining, in response to said sums of the squares of successive ones of said components corresponding to said square wave test signal, the viability of processing through said processing channel.

15. A method of testing the viability of processing of an AC input signal having a range of magnitudes and a range of frequencies, through a processing channel including a low pass filter, said method comprising:
providing a square wave signal having a frequency within said range of frequencies and a magnitude related to said range of magnitudes;
periodically selecting said square wave signal instead of said input signal for application to said processing channel; and
determining, in response to the output of said processing channel corresponding to said selected wave signal, the viability of processing through said processing channel.

16. A method according to claim 14 wherein:
said providing step provides a plurality of square wave signals at diverse frequencies within said range of frequencies; and
said selecting step includes selecting one of said plurality of square wave signals.

17. Apparatus for testing the viability of processing of an AC input signal having a range of magnitudes and a range of frequencies, through a processing channel including a low pass filter, comprising:
means for providing a square wave signal having a frequency within said range of frequencies and a magnitude related to said range of magnitudes;
means for periodically selecting said square wave signal instead of said input signal for application to said processing channel; and
means for determining, in response to the output of said processing channel corresponding to said selected wave signal, the viability of processing through said processing channel.
